(19) United States
(12) Patent Application Publication
(10) Pub. No.: US 2014/0035105 A1
(43) Pub. Date: Feb. 6, 2014

(54) SEMICONDUCTOR DEVICE, METHOD FOR MANUFACTURING SEMICONDUCTOR DEVICE, AND BASE MEMBER FOR SEMICONDUCTOR DEVICE FORMATION

(71) Applicant: KABUSHIKI KAISHA TOSHIBA, Tokyo (JP)

(72) Inventors: Akira KOMATSU, Ishikawa-ken (JP); Kaori FUSE, Kanagawa-ken (JP); Hiroto MISAWA, Ishikawa-ken (JP)

(73) Assignee: KABUSHIKI KAISHA TOSHIBA, Tokyo (JP)

(21) Appl. No.: 13/846,863

(22) Filed: Mar. 18, 2013

(30) Foreign Application Priority Data
Aug. 3, 2012 (JP) 2012-172654

(51) Int. Cl. H01L 29/06; H01L 21/18

(52) U.S. Cl. CPC H01L 29/06; H01L 21/185
USPC 257/618; 257/650; 438/455

(57) ABSTRACT

According to one embodiment, a method for manufacturing a semiconductor device includes forming semiconductor layers in a plurality of first regions on a semiconductor wafer. The plurality of first regions are separated from each other. The method includes forming elements in the semiconductor layers. The method includes bonding an insulating plate made of an inorganic material in a second region on the semiconductor wafer. The second region excludes the first regions. The method includes performing singulation for each of the semiconductor layers by cutting the semiconductor wafer and the insulating plate along a dicing line configured to pass through only the second region.

### CROSS-REFERENCE TO RELATED APPLICATIONS

This application is based upon and claims the benefit of priority from the prior Japanese Patent Application No. 2012-172654, filed on Aug. 3, 2012; the entire contents of which are incorporated herein by reference.

1. Field

Embodiments described herein relate generally to a semiconductor device, a method for manufacturing the same and a base member for a semiconductor device formation.

2. Background

In a power semiconductor device, a high breakdown voltage is necessary for the device and for the terminal portion. Conventionally, the breakdown voltage necessary for the terminal portion has been realized by making trenches in the semiconductor wafer and forming an insulating member by coating an insulating material into the trenches.

### BRIEF DESCRIPTION OF THE DRAWINGS

FIGS. 1A to 1F are cross-sectional views of processes showing a method for manufacturing a semiconductor device according to an embodiment;

FIG. 2 is a plan view showing a base member for a semiconductor device formation according to the embodiment;

FIG. 3 is a process plan view showing the method for manufacturing the semiconductor device according to the embodiment;

FIG. 4A is a plan view showing the semiconductor device according to the embodiment; and FIG. 4B is a cross-sectional view of FIG. 4A;

FIGS. 5A to 5F are cross-sectional views of processes showing a method for manufacturing a semiconductor device according to a comparative example; and

FIGS. 6A and 6B are process plan views showing the method for manufacturing the semiconductor device according to the comparative example.

### DETAILED DESCRIPTION

In general, according to one embodiment, a method for manufacturing a semiconductor device includes forming semiconductor layers in a plurality of first regions on a semiconductor wafer. The plurality of first regions are separated from each other. The method includes forming elements in the semiconductor layers. The method includes bonding an insulating plate made of an inorganic material in a second region on the semiconductor wafer. The second region excludes the first regions. The method includes performing singulation for each of the semiconductor layers by cutting the semiconductor wafer and the insulating plate along a dicing line configured to pass through only the second region.

In general, according to one embodiment, a base member for a semiconductor device formation includes a semiconductor wafer, an insulating plate made of an inorganic material having a plurality of openings, and semiconductor layers disposed in interiors of the openings. The insulating plate is bonded to the semiconductor wafer.

In general, according to one embodiment, a semiconductor device includes a semiconductor substrate, a semiconductor layer and an insulating plate. The semiconductor layer is provided in a central region on the semiconductor substrate. The insulating plate is made of an inorganic material. The insulating plate is disposed in a peripheral region on the semiconductor substrate around the semiconductor layer. The insulating plate is bonded to the semiconductor substrate.

An embodiment of the invention will now be described with reference to the drawings.

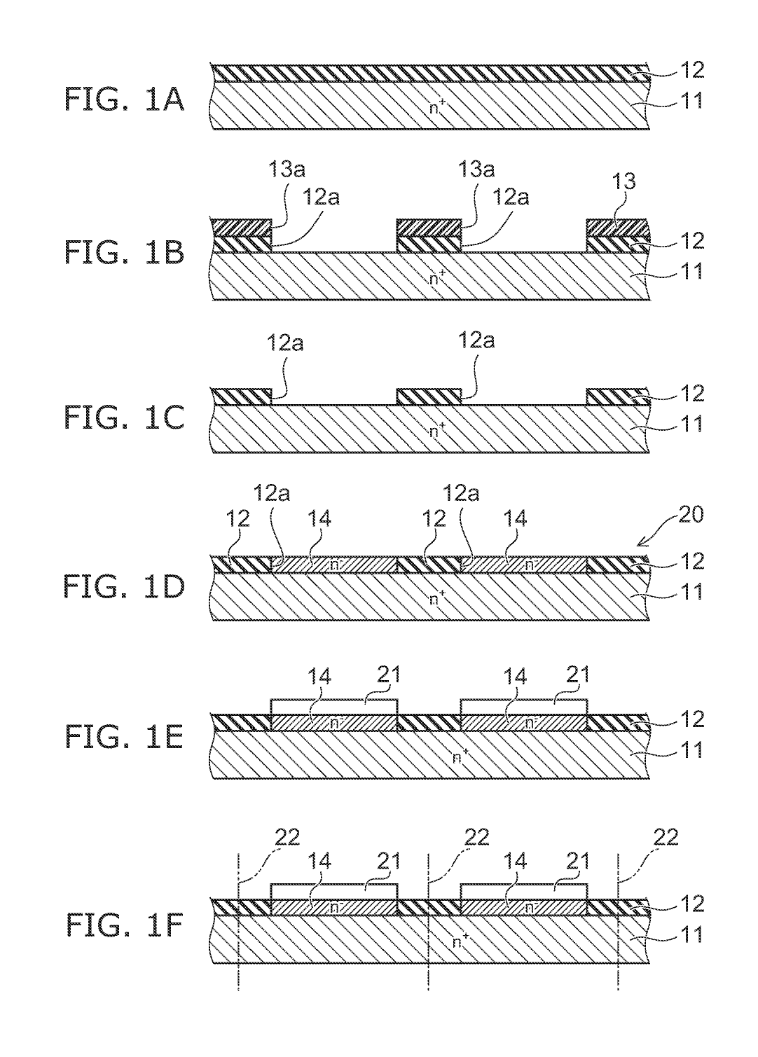

FIGS. 1A to 1F are cross-sectional views of processes showing a method for manufacturing a semiconductor device according to the embodiment.

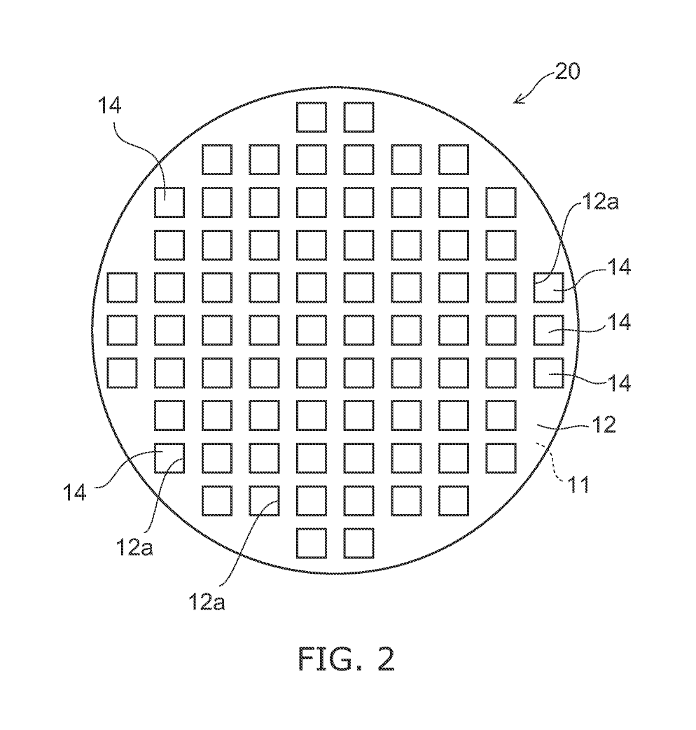

FIG. 2 is a plan view showing a base member for a semiconductor device formation according to the embodiment.

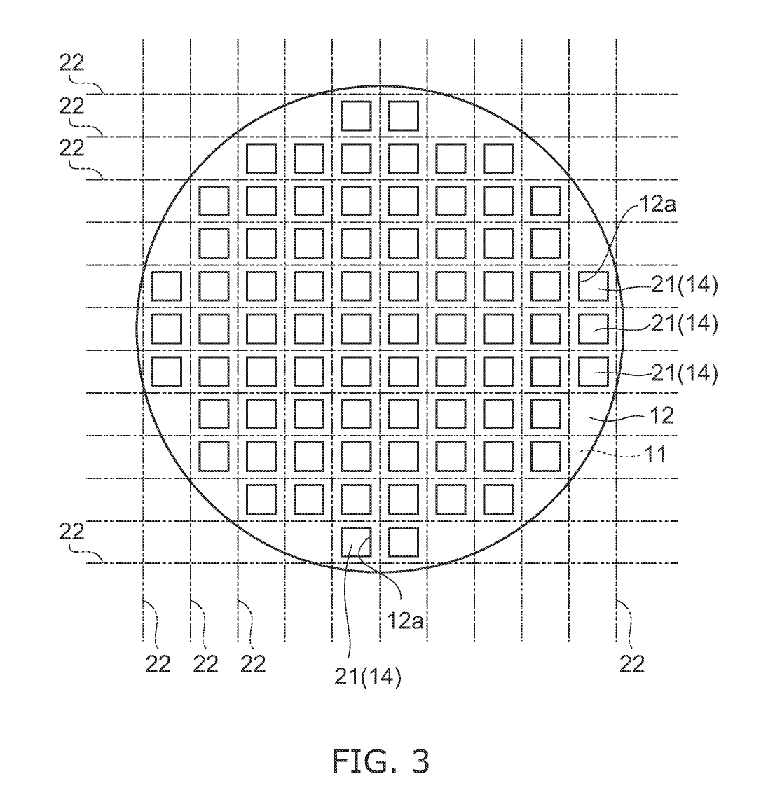

FIG. 3 is a process plan view showing the method for manufacturing the semiconductor device according to the embodiment.

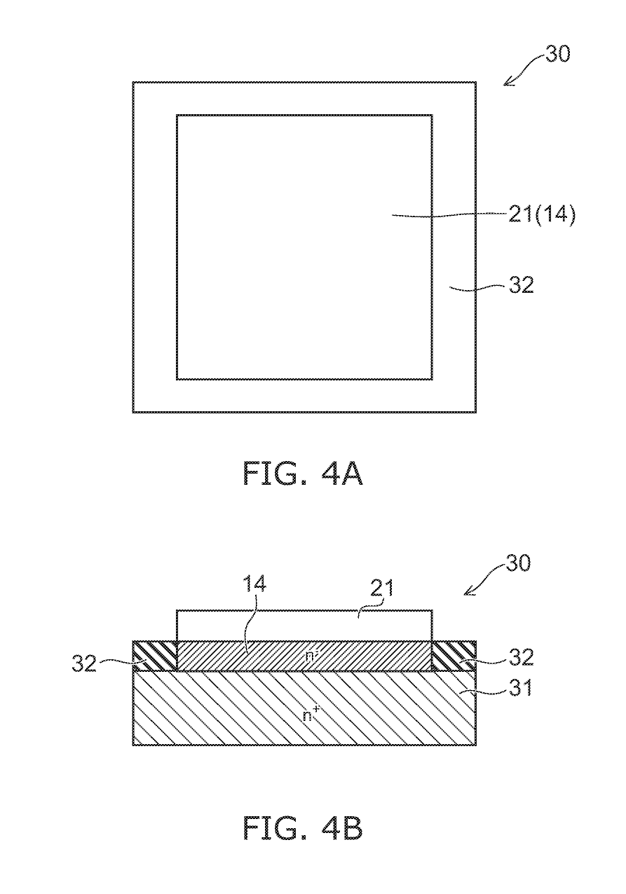

FIG. 4A is a plan view showing the semiconductor device according to the embodiment; and FIG. 4B is a cross-sectional view of FIG. 4A.

The method for manufacturing the semiconductor device according to the embodiment may be divided into a process of making the base member for a semiconductor device formation and a process of forming elements in the base member for a semiconductor device formation and performing singulation.

First, the first half of the method for manufacturing the semiconductor device according to the embodiment, i.e., the process of making the base member for a semiconductor device formation, will be described.

As shown in FIG. 1A, a silicon wafer 11 and a glass plate 12 are prepared. The silicon wafer 11 is, for example, a wafer of an n⁺ conductivity type. The glass plate 12 has a disc configuration; the diameter of the glass plate 12 is about the same as the diameter of the silicon wafer 11; and the thickness of the glass plate 12 is, for example, 30 to 50 μm (microns).

Then, the glass plate 12 is bonded and adhered to the upper surface of the silicon wafer 11 by anodic bonding. Namely, a voltage of about several hundred volts is applied while heating to about several hundred degrees in the state of the glass plate 12 contacting the silicon wafer 11. Thereby, ions inside the glass plate 12 move to the bonding interface and form covalent bonds with silicon atoms inside the silicon wafer 11. As a result, the glass plate 12 is bonded securely to the silicon wafer 11.

Continuing as shown in FIG. 1B, a resist pattern 13 is formed by forming a resist film on the glass plate 12 and by patterning the resist film. Multiple openings 13a are made in the resist pattern 13 to be separated from each other and arranged in a matrix configuration. The size of each of the openings 13a is slightly smaller than the chip size; and the configuration of each of the openings 13a is, for example, a rectangle.

Then, the glass plate 12 is selectively removed by performing etching using the resist pattern 13 as a mask. The etching is performed by, for example, wet etching using BHF (buffered hydrofluoric acid) as the etchant or by dry etching using trifluoromethane gas (CHF₃) as the etching gas. Thereby, multiple openings 12a are made in the glass plate 12. The upper surface of the silicon wafer 11 is exposed inside the openings 12a.

Continuing as shown in FIG. 1C, the resist pattern 13 is removed.

Then, as shown in FIG. 1D, a silicon layer 14 is epitaxially grown in the interior of each of the openings 12a on the upper surface of the silicon wafer 11 with the upper surface of the silicon wafer 11 as the starting point. At this time, the height of the upper surface of the silicon layer 14 is about the same as the height of the upper surface of the glass plate 12. The conductivity type of the silicon layer 14 is, for example, the n⁻ type. Thereby, the base member for a semiconductor device formation 20 according to the embodiment (hereinbelow, also referred to as simply the base member 20) is made.

As shown in FIG. 1D and FIG. 2, the silicon wafer 11, the glass plate 12, and the silicon layer 14 are provided in the base member 20. The glass plate 12 is bonded to the silicon wafer 11 by anodic bonding; and the multiple openings 12a are made in the glass plate 12 to be arranged in a matrix configuration. The thickness of the glass plate 12 is, for example, 30 to 50 μm. The silicon layer 14 is disposed in the interior of each of the openings 12a of the glass plate 12 and is epitaxially grown from the upper surface of the silicon wafer 11. The lower surface of the silicon layer 14 contacts the silicon wafer 11; and the upper surface of the silicon layer 14 is at substantially the same height as the upper surface of the glass plate 12. For example, the conductivity type of the silicon wafer 11 is the n⁺ type; and the conductivity type of the silicon layer 14 is the n⁻ type.

The latter half of the method for manufacturing the semiconductor device according to the embodiment, i.e., the process of forming the elements in the base member for a semiconductor device formation and performing the singulation, will now be described.

As shown in FIG. 1E, an element 21 is formed in and on each of the silicon layers 14 of the base member 20. The element 21 is, for example, a MOSFET (Metal-Oxide-Semiconductor Field-Effect Transistor) and includes metal interconnects, etc., connected to the MOSFET. For convenience of illustration in each of the drawings, the element 21 is shown as a rectangular block.

Then, as shown in FIG. 1F and FIG. 3, a dicing line 22 that does not pass through the silicon layer 14 is set in the base member 20. In other words, the dicing line 22 passes through the stacked body made of the silicon wafer 11 and the glass plate 12. One silicon layer 14 is included in each region enclosed with the dicing line 22. Then, the base member 20 in which the elements 21 are formed is singulated for each of the silicon layers 14 by cutting the silicon wafer 11 and the glass plate 12 along the dicing line 22. Thereby, the semiconductor device 30 according to the embodiment is formed. At this time, the silicon wafer 11 is cut into multiple silicon substrates 31; and the glass plate 12 is cut into multiple glass plates 32 having frame-like configurations.

As shown in FIGS. 4A and 4B, the silicon substrate 31 is provided in the semiconductor device 30 thus manufactured. The silicon substrate 31 has a rectangular plate configuration; and the conductivity type of the silicon substrate 31 is the n⁺ type. One silicon layer 14 is provided in the central region on the silicon substrate 31. The glass plate 32 having the frame-like configuration is provided to enclose the silicon layer 14 in the peripheral region on the silicon substrate 31. The thickness of the glass plate 32 is, for example, 30 to 50 μm; and the width of the glass plate 32 also is, for example, 30 to 50 μm. The glass plate 32 is anodically bonded to the silicon substrate 31. The element 21 is formed in and on the silicon layer 14. As described above, the silicon layer 14 is epitaxially grown from the silicon substrate 31; and the conductivity type of the silicon layer 14 is the n⁻ type. The semiconductor device 30 is, for example, a power discrete chip.

Effects of the embodiment will now be described.

As shown in FIGS. 4A and 4B in the embodiment, the glass plate 32 having the thickness of 30 to 50 μm and the width of 30 to 50 μm is provided in the peripheral region on the silicon substrate 31 of the semiconductor device 30. Thereby, a high breakdown voltage can be realized because the terminal portion of the semiconductor device 30 is formed of glass.

A high breakdown voltage can be realized by the thickness and the width of the glass plate 32 being not less than 30 μm. Also, by the thickness and the width of the glass plate 32 being not more than 50 μm, the glass plate 32 can be effectively prevented from peeling from the silicon substrate 31 due to the difference of the coefficients of thermal expansion between the silicon substrate 31 and the glass plate 32. Therefore, it is favorable for the thickness and the width of the glass plate 32 to be 30 to 50 μm.

In the embodiment, a thick insulating member can be formed easily at low cost to ensure the breakdown voltage of the terminal portion because the glass plate 12 is adhered to the silicon wafer 11 by anodic bonding in the process shown in FIG. 1A. Further, because the insulating member (the glass plate 12) that originally has a plate configuration is bonded to the silicon wafer 11, the coverage (the fillability) is not problematic as in the case where the insulating member is formed by depositing an insulating material on the silicon wafer 11.

The thermal stability can be increased by the terminal structure of the semiconductor device 30 being formed of the glass plate 32. Thereby, it is possible to use high-temperature processes when forming the element 21; and the degrees of freedom of the processes increase.

In the embodiment, the silicon layer 14 is formed inside the opening 12a of the glass plate 12 in the process shown in FIG. 1D; and the height of the upper surface of the silicon layer 14 is substantially the same as the height of the upper surface of the glass plate 12. Thereby, the upper surface of the base member 20 is substantially flat; and the handling can be similar to that of a general wafer. As a result, a discrete chip can be manufactured easily by applying normal wafer MOS processes to the base member 20.

A comparative example will now be described.

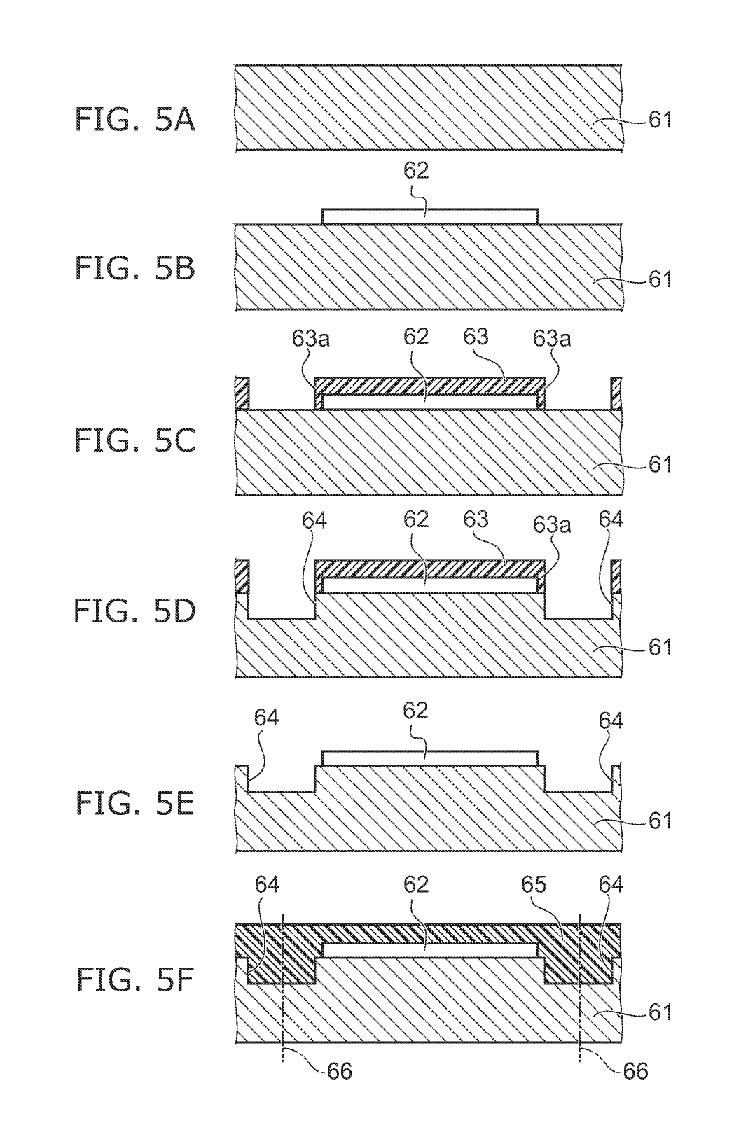

FIGS. 5A to 5F are cross-sectional views of processes showing a method for manufacturing a semiconductor device according to the comparative example.

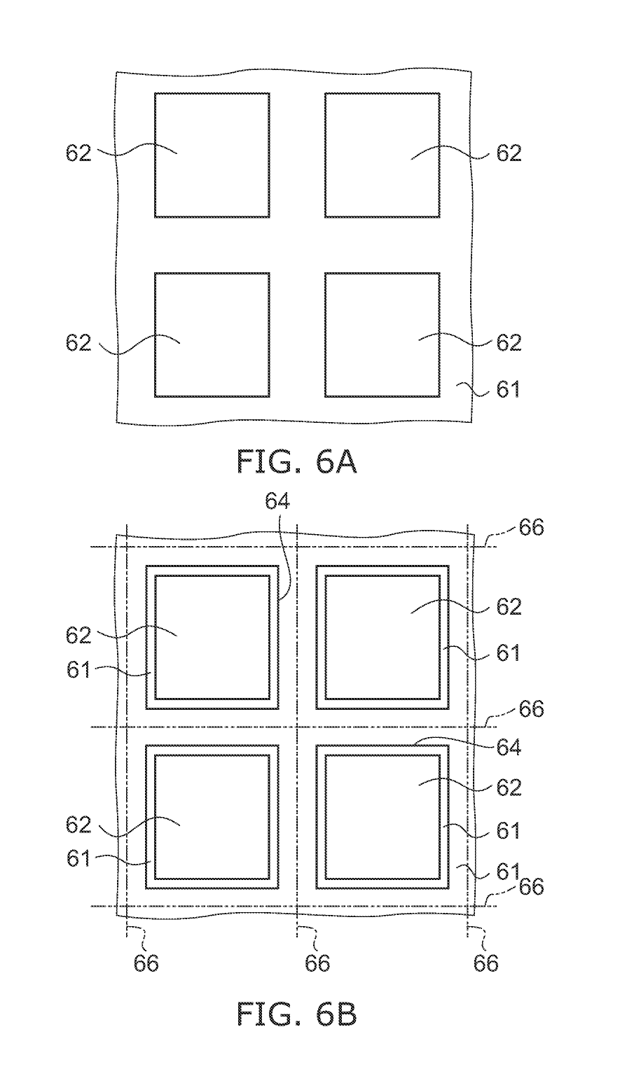

FIGS. 6A and 6B are process plan views showing the method for manufacturing the semiconductor device according to the comparative example.

First, as shown in FIG. 5A, a silicon wafer 61 is prepared.

Then, as shown in FIG. 5B and FIG. 6A, an element 62 such as a MOSFET, etc., is formed in and on the silicon wafer 61. The element 62 also includes metal interconnects.

Continuing as shown in FIG. 5C, a resist pattern 63 that is chip-sized is formed to cover the region where the element 62 is formed. The configuration of each of the portions of the resist pattern 63 is rectangular; and an opening 63a having a lattice configuration is made between each of the portions of the resist pattern 63.

Then, as shown in FIG. 5D, a trench 64 is made in the upper surface of the silicon wafer 61 by performing RIE (reactive ion etching) using the resist pattern 63 as a mask. The width of the trench 64 is 50 μm; and the depth also is 50 μm.

Continuing as shown in FIG. 5E and FIG. 6B, the resist pattern 63 is removed.

Then, as shown in FIG. 5F, an insulating film 65 made of a resin material such as, for example, polyimide, etc., is formed on the entire surface by spin coating. At this time, the insulating film 65 is filled also into the interior of the trench 64.

Continuing, singulation is performed for each of the elements 62 by cutting the silicon wafer 61 and the insulating film 65 along a dicing line 66 that is set to pass through the trench 64 but not pass through the elements 62. Thereby, the semiconductor device according to the comparative example is manufactured. The terminal structure of the semiconductor device is formed of the insulating film 65.

In the comparative example, it is necessary for the interior of the trench 64 which has a depth of 50 μm to be filled with the insulating film 65. Therefore, a vapor deposition method such as CVD (chemical vapor deposition), etc., cannot be employed as the method for forming the insulating film 65; and it is necessary to use a coating method such as spin coating, etc. Accordingly, the material of the insulating film 65 is limited to a material that can be formed as a film by coating, e.g., a resin material such as, for example, polyimide, etc. Moreover, the insulating film 65 is limited to being a material having a low curing temperature because the insulating film 65 is formed after the formation of the metal interconnects included in the elements 62. Due to these constraints, the insulating film 65 is a film having low thermal stability. As a result, the degrees of freedom of the processes when manufacturing the semiconductor device decrease. For example, although the tolerable temperature of the polyimide is about 350° C., the insulating film 65 must be formed after forming the elements 62 because the annealing temperature to form the elements 62 must be about 900 to 1000° C.

Even in the case of a coating-type resin material, it is not easy to fill the trench 64 which has a depth of 50 μm; and there are cases where multiple coating processes are necessary to ensure coverage. Thereby, the manufacturing cost of the semiconductor device undesirably increases. Moreover, when the insulating film 65 is made of a thick resin material formed with a thickness of about 50 μm, there are cases where cracks undesirably occur in the insulating film 65 due to thermal shrinkage in the thermal curing of the resin material.

Conversely, according to the embodiment described above, an insulating member that is strong and has high thermal stability can be formed easily at low cost with the desired thickness by adhering the glass plate 12 to the silicon wafer 11. The base member 20 is made by making the openings 12a in the glass plate 12 and forming the silicon layer 14 in the interiors of the openings 12a; and the base member 20 can be handled similarly to a normal silicon wafer. At this time, the element 21 can be formed in the silicon layer 14 after the glass plate 12 is adhered to the silicon wafer 11 because the thermal stability of the glass plate 12 is high. Subsequently, the semiconductor device 30 in which the glass plate 32 is provided in the outer circumferential portion can be manufactured by the dicing described above.

Although an example is illustrated in the embodiments described above in which a glass plate is used as the insulating plate included in the terminal structure, this is not limited thereto. It is sufficient for an insulating plate to be made of, for example, an inorganic material such as a sapphire plate, etc. Thereby, a terminal structure having high thermal stability can be realized. Although an example is illustrated in the embodiments described above in which a silicon substrate is used as the semiconductor substrate, the semiconductor substrate is not limited thereto and may be a GaN substrate, a SiC substrate, etc. Although an example is illustrated in the embodiments described above in which the semiconductor device is a power discrete chip, the semiconductor device is not limited thereto and may be another semiconductor device or a microstructure such as a MEMS (Micro Electro Mechanical System), a sensor, etc.

Although an example is illustrated in the embodiments described above in which the silicon layers 14 and the elements 21 are formed after bonding the glass plate 12 to the silicon wafer 11, the timing of the bonding of the glass plate 12 to the silicon wafer 11 is arbitrary. For example, silicon layers may be formed in multiple element regions that are separated from each other on the silicon wafer; the elements may be formed in the silicon layers; and subsequently, a glass plate in which openings are made beforehand may be bonded to the silicon wafer in an inter-element region excluding the element regions. At this time, the glass plate covers the inter-element region of the silicon wafer; and the openings of the glass plate are positioned in the element regions of the silicon wafer. Subsequently, singulation is performed for each of the silicon layers by setting a dicing line that passes through only the inter-element region and by cutting the silicon wafer and the glass plate along the dicing line.

According to the embodiments described above, a semiconductor device, a method for manufacturing the semiconductor device, and a base member for a semiconductor device formation that are easy to manufacture and have terminal portions having high breakdown voltages can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device, comprising:
forming semiconductor layers in a plurality of first regions on a semiconductor wafer, the plurality of first regions being separated from each other;
forming elements in the semiconductor layers;
bonding an insulating plate made of an inorganic material in a second region on the semiconductor wafer, the second region excluding the first regions; and
performing singulation for each of the semiconductor layers by cutting the semiconductor wafer and the insulating plate along a dicing line configured to pass through only the second region.

2. The method according to claim 1, wherein
the semiconductor wafer is a silicon wafer,
the insulating plate is a glass plate, and
the insulating plate is bonded to the semiconductor wafer by anodic bonding.

3. The method according to claim 1, wherein the semiconductor layers are formed by being epitaxially grown on the semiconductor wafer.

4. A method for manufacturing a semiconductor device, comprising:
bonding an insulating plate made of an inorganic material to a semiconductor wafer;
making a plurality of openings in the insulating plate;
forming semiconductor layers in interiors of the openings;
forming elements in the semiconductor layers; and
performing singulation for each of the semiconductor layers by cutting the semiconductor wafer and the insulating plate along a dicing line configured not to pass through the semiconductor layers.

5. The method according to claim 4, wherein
the semiconductor wafer is a silicon wafer,
the insulating plate is a glass plate, and
the insulating plate is bonded to the semiconductor wafer by anodic bonding.

6. The method according to claim 4, wherein the semiconductor layers are formed by being epitaxially grown on the semiconductor wafer.

7. A method for manufacturing a semiconductor device, comprising:
forming elements in semiconductor layers included in a base member, the base member including a semiconductor wafer and an insulating plate having a plurality of openings, the semiconductor layers being disposed in interiors of the openings, the insulating plate being made of an inorganic material bonded to the semiconductor wafer; and
singulating the base member for each of the semiconductor layers by cutting the semiconductor wafer and the insulating plate along a dicing line configured not to pass through the semiconductor layers.

8. The method according to claim 7, wherein
the semiconductor wafer is a silicon wafer,
the insulating plate is a glass plate, and
the insulating plate is bonded to the semiconductor wafer by anodic bonding.

9. The method according to claim 7, wherein the semiconductor layers are formed by being epitaxially grown on the semiconductor wafer.

10. A base member for a semiconductor device formation, comprising:
a semiconductor wafer;
an insulating plate made of an inorganic material having a plurality of openings, the insulating plate being bonded to the semiconductor wafer; and
semiconductor layers disposed in interiors of the openings.

11. The base member according to claim 10, wherein
the semiconductor wafer is a silicon wafer, and
the insulating plate is a glass plate.

12. The base member according to claim 10, wherein the semiconductor layers contact the semiconductor wafer.

13. A semiconductor device, comprising:
a semiconductor substrate;
a semiconductor layer provided in a central region on the semiconductor substrate; and
an insulating plate made of an inorganic material disposed in a peripheral region on the semiconductor substrate around the semiconductor layer, the insulating plate being bonded to the semiconductor substrate.

14. The device according to claim 13, wherein
the semiconductor substrate is a silicon substrate, and
the insulating plate is a glass plate.

15. The device according to claim 13, wherein the semiconductor layer contacts the semiconductor substrate.
